(19) United States
(12) Patent Application Publication
(10) Pub. No.: US 2019/0222148 A1
(43) Pub. Date: Jul. 18, 2019

(54) ENERGY HARVESTING PAD MADE FROM PIEZOELECTRIC MATERIALS

(71) Applicant: Esha M. Patel, Lake City, FL (US)

(72) Inventor: Esha M. Patel, Lake City, FL (US)

(21) Appl. No.: 15/926,379

(22) Filed: Mar. 20, 2018

Related U.S. Application Data
(60) Provisional application No. 62/475,327, filed on Mar. 23, 2017.

(51) Int. Cl. H02N 2/18; H02N 2/00; H01L 41/113

(52) U.S. Cl. CPC H02N 2/186; H01L 41/1132; H02N 2/0075

(57) ABSTRACT

An energy harvesting apparatus (10) generates energy using of piezoelectric sensors (S) mounted on a base (B). Outputs from the sensors are supplied to rectifier bridge circuits (R). Outputs from the bridge circuits charge an energy storage capacitor (C). When the pad is in use, the capacitor stores the energy generated through kinetic power and this stored energy is subsequently used to charge an electronic device connected to the apparatus for this purpose.

### CROSS-REFERENCE TO REFERENCE TO RELATED APPLICATIONS

This application is based on and claims the benefit of U.S. provisional patent application 62/475,327 filed Mar. 23, 2017, which is incorporated herein by reference.

### STATEMENT REGARDING FEDERALLY SPONSORED RESEARCH OR DEVELOPMENT

N/A

### BACKGROUND OF THE INVENTION

This invention relates to renewable sources of energy; and more particularly, to an energy harvesting writing pad including, inter alia, multiple bridge rectifier and other circuits capable of storing energy in a capacitor. Through usage of the pad throughout the day, energy is stored in the capacitor and is available for use to power other devices. It will be understood that the more frequent the use of the pad, more energy is generated and stored and is thus available. Renewable energy has many advantages for mankind and there are multiple types of renewable energy including wind, solar, geothermal, hydroelectric, and biomass. Piezoelectricity is also considered a renewable source of energy as it generates power through a constant vibration and/or pressure on a suitable material.

These renewable resources have many advantages, and each type has unique benefits. A first benefit is that it decreases emissions which produce global warming. Such emissions are mainly caused from human activities such as the combustion of fossil fuels. A second benefit is the improvement of the world's population health, and the quality of the environment. Another benefit is that the potential vast energy supply and associated resources can help increase job growth and the resulting economic benefits. A further benefit is that a renewable energy system is resilient and energy reserves do not deplete.

There are a few significant differences between renewable and nonrenewable energy resources. One is that nonrenewable resources such as coal, nuclear, oil, and natural gas have limited availability. Examples of nonrenewable resources include and these have been used for thousands of years. Over the past 30 years, there has been increasing concern about both global warming and the depletion of our nonrenewable resources. To combat this issue multiple attempts have been made to find more efficient replacements for nonrenewable resources.

The piezoelectric effect is a process for creating an electrical charge resulting from an applied mechanical stress. “Piezoelectricity” is derived from the Greek word “piezein”, meaning “to squeeze or press” (The Piezoelectric Effect). Note: All references cited in this application are listed in Exhibit A. The effect is a reversible one in that there can be a converse or direct piezoelectric effect. That is, when a piezoelectric material is subjected to a mechanical stress, a shifting of the positive and negative charges in the material takes place. If the force is reversed, another, outer, electrical field stretches the piezoelectric material.

As described hereinafter, the present invention utilizes the piezoelectric effect to generate electricity and do so on a renewable basis.

### BRIEF SUMMARY OF THE INVENTION

The present disclosure is directed to a renewable energy device which generates electricity using the piezoelectric effect. The device employs a circuit board or pad manufactured from a piezoelectric material and incorporating bridge rectifier circuits, resistors, capacitors, and diodes, these electrical circuit elements being arranged in series and parallel circuits.

The device utilizes kinetic energy which is produced by the application of pressure to and motion of the pad with the energy produced from a plurality of piezoelectric sensors strategically placed about the pad. The energy produced by the sensors is stored in at least one capacitor, or multiple capacitors forming a capacitor bank.

The device is used, for example, with a writing pad such as used by students with pressure and movement of the pad, caused by the act of writing on the pad, resulting in energy being produced and stored. The stored energy is then used, for example, to charge other electronic devices such as cell phones, tablets, PCs, PDAs, etc. used by the student or others. Future applications include an efficient energy harvesting pad that can charge any type of device (phone, tablet, etc.) after a day's worth of “writing”.

The device is low cost, easy to use, and reliable.

Other objects will be in part apparent and in part pointed out hereinafter.

### BRIEF DESCRIPTION OF THE SEVERAL VIEWS OF THE DRAWINGS

The accompanying figures, together with detailed description which follows, form part of the specification and illustrate the various embodiments described in the specification.

FIG. 1A is a simplified representation of an energy harvesting pad of the present invention;

FIG. 1B is a schematic of a diode bridge rectifier circuit;

FIGS. 2-6 are respective illustrations of a piezoelectric sensor, bridge rectifier circuit and other circuit components used in the device;

FIGS. 7A-7C are charts illustrating the amount of voltage obtained form trials at 5, 10, 20, and 30 rolls respectively;

FIG. 8 is a chart of the average of volts gained from the 5, 10, 20, and 30 rolls respectively;

FIGS. 9A-9D are each a scatter plot graph illustrating the millivolts gained from rolling the dowels 5, 10, 20, and 30 times respectively;

FIG. 10 is a bar graph showing the average amount of millivolts gained for the number of rolls 5, 10, 20, and 30 respectively; and,

FIG. 11 is a table showing the standard deviation for each of the tests at 5, 10, 20, and 30 rolls respectively.

### DETAILED DESCRIPTION OF INVENTION

The following detailed description illustrates the invention by way of example and not by way of limitation. This description clearly enables one skilled in the art to make and use the invention, and describes several embodiments, adaptations, variations, alternatives and uses of the invention, including what is presently believed to be the best mode of carrying out the invention. Additionally, it is to be understood that the invention is not limited in its application to the details of construction and the arrangement of components set forth in the following description or illustrated in the drawings. The invention is capable of other embodiments and of being practiced or carried out in various ways. Also, it will be understood that the phraseology and terminology used herein is for the purpose of description and should not be regarded as limiting.

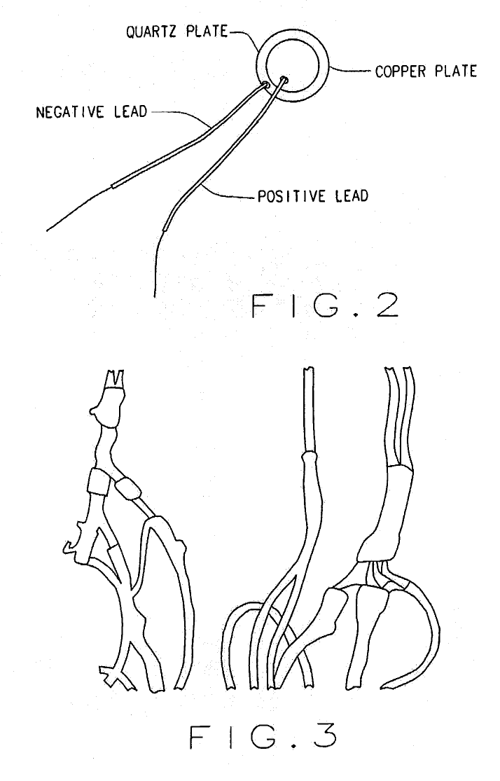

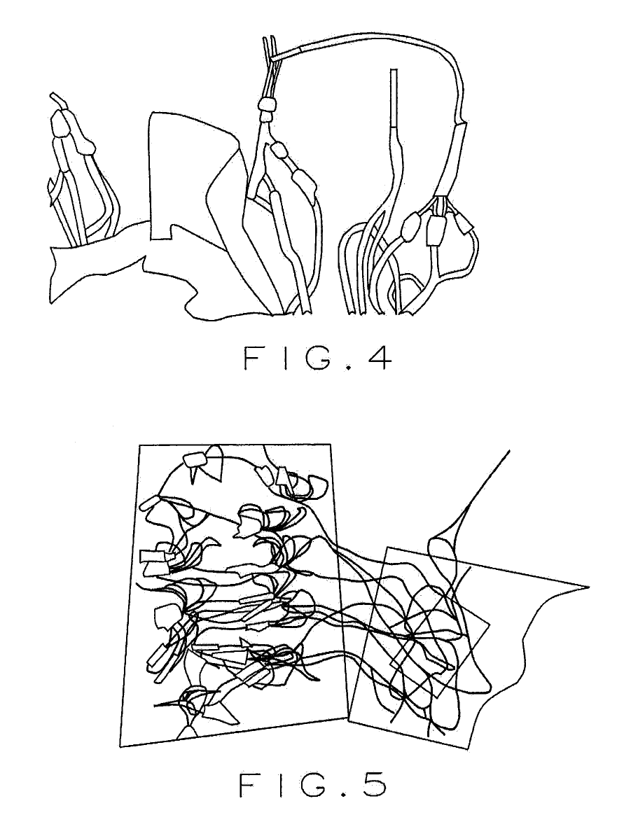

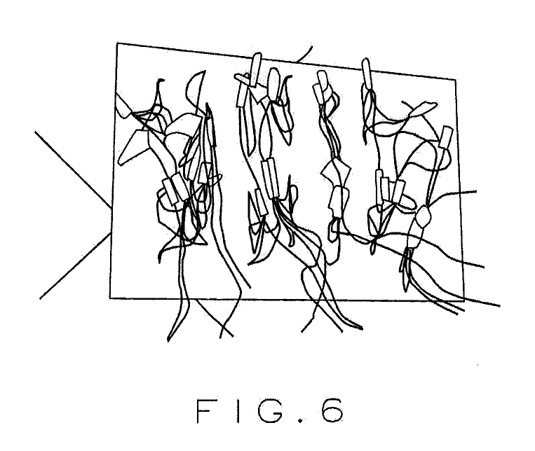

Several man-made or natural materials exhibit the piezoelectric effect. FIG. 2, for example, illustrates a piezoelectric sensor S made of Quartz and this type of sensor is used in the device. Other applications where piezoelectricity is used include motors and other power sources, sensors such as pressure sensors which detect pressure either from induced voltage or frequency shifts, transducers, gyroscopes, ultrasound equipment, microphones, watches and clocks (The Piezoelectric Effect). With respect to microphones, the vocal sound (i.e., motion or vibration) results in the projection of a louder sound because of the piezoelectric effect.

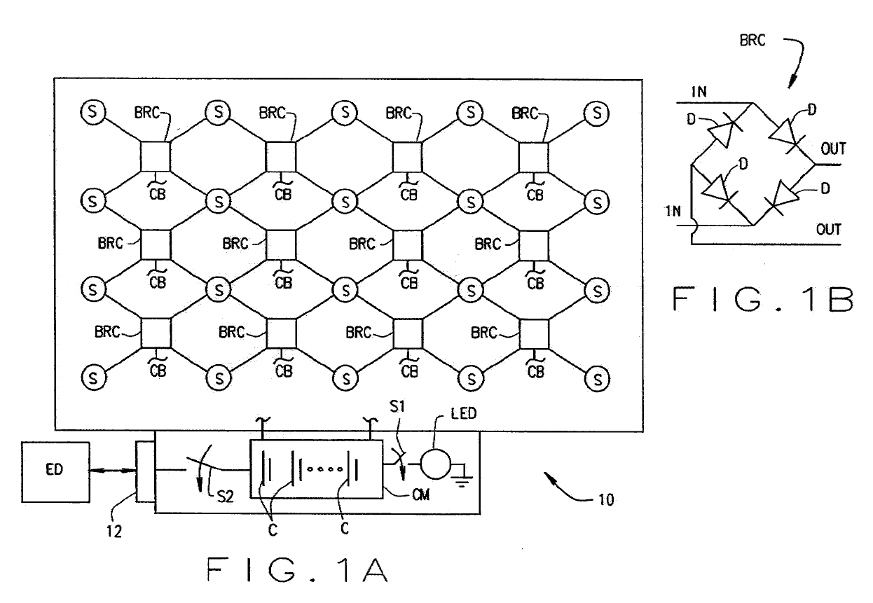

In accordance with the present invention, and as shown in FIG. 1A, an energy harvesting pad 10 generates energy with the use of piezoelectric sensors S. The piezoelectric sensors S are strategically placed onto a base or plate B. All the wires or leads of these piezoelectric sensors are connected in parallel. The piezoelectric sensors S are arranged in rows, as shown in FIG. 1A, and the electrical energy generated by each row of sensors is directed to a bridge rectifier circuit BRC. Each bridge rectifier circuit BRC is comprised of diodes D connected as shown in FIG. 1B.

Electrical energy from each bridge rectifier circuit flows to one or more capacitors C. If there is more than one capacitor C, then the capacitors comprise a capacitor bank CB. When the pad is in use; i.e., someone is moving it or writing upon it, a capacitor C stores the energy generated through the kinetic power. An LED mounted on the pad is used to indicate generation of energy. A switch 51 also mounted on the pad controls flow of energy to the LED.

Pad 10 includes a connector 12 to which other electronic devices ED to be charged are connected to the pad. Capacitor bank CB is electrically connected to connector 12 through a switch S2. When a device to be charged is connected to connector 12, and switch S2 is activated, the capacitors C are discharged through the connector into the electronic device to charge or recharge the device.

The list of materials and steps involved in making the apparatus are set forth in Addendum A to this application.

Testing of the apparatus is described in Addendum B.

Analysis of the test results is set forth in Addendum C.

In view of the above, it will be seen that the several objects and advantages of the present disclosure have been achieved and other advantageous results have been obtained.

Addendum A

List of materials and steps for manufacturing the apparatus
Applicator
2 Alligator Clips
Black and Red Wire for Volt Meter
1 capacitor (4.7 μF, 160 V)
Drill
⅜ inch Drill Bit
Electric Tape
Flat Surface
1 Green LED
Masking Tape
1 Notebook (28.4×21.4 cm)
42 Piezoelectric Sensors
1 Resistor (2.2Ω)
Silicone Cement
Ruler
Screwdriver
Soldering Iron
Soldering Wire
Switch
25 Toothpicks
Volt Meter
Wire for circuits
Wooden board (32.5×21.9 cm)
Wooden dowel
28 1N4184 Zener Diodes

The following safety procedures were used:
Keeping the soldering iron on a stand when not in use.
Wearing a mask to prevent breathing in fumes of silicone cement.
Using gloves when dealing with silicone cement.
Seeking assistance or supervision of an adult when soldering, drilling, or working on electrical components.
Tying or keeping long hair back when working on the project.
Wearing long sleeves and gloves to protect ones self from burning one's fingers on the tip of the soldering iron.

The following is the list of steps used in fabricating and testing the pad:

1. Gather all the materials.

2. Using a wire stripper, strip off two centimeters of the piezoelectric sensor's positive (red) and negative (black) wires. Do this for 42 sensors in total.

3. Get a piece of a wooden board and cut it to a size of 32.5×21.9 cm.

4. Draw a 6 cm by 7 cm grid on the board. They should be 4.3 by 4.5 cm squares.

5. Using the ⅜′ drill bit, drill a hole 2.3 cm from the bottom left corner of each box in the row.

6. For the next row, drill a hole at the bottom left corner of each box.

7. For the remainder rows, alternate between steps 5 and 6 until all 7 rows are complete.

8. Cut the ends off of all 25 toothpicks leaving the uniform sections and then cut the sections into two centimeter pieces.

9. Place the pieces from step 8 onto the wooden board 1.5 cm up from the hole and use the applicator to secure the pieces with silicone cement.

10. Place the piezo sensors face side up (the side with the quartz plate) in each hole onto the toothpick pieces.

11. Apply silicone cement on the top of each sensor. Make sure that the bottom of each disk touches the board and secure the leads and disks with ample silicone cement.

12. Allow the cement to dry for two days.

13. Cut ten 5 cm wires and strip off half a centimeter on each end.

14. Solder all 6 positive leads of the sensors in row 1 with six wires in parallel. The sixth wire will be left as a positive lead for row 1.

15. Solder all 6 negative leads of the sensors in row 1 with six wires in parallel. The sixth wire will be left as a negative lead for row 1.

16. Repeat steps 14 and 15 for the remaining six rows.

17. Create and solder a bridge rectifier using four diodes alternating between positive to negative on each end.

18. On the positive end of the bridge rectifier, solder the positive lead for row 1 and the negative lead to the negative end of the bridge rectifier.

19. Cut a 6″ wire and cut a half a centimeter off both ends of it. Solder this wire to the top connection of the bridge rectifier.

20. Repeat steps 17 through 19 until all rows are complete.

21. Solder the bridge rectifier output from row 1 to the bridge rectifier output of row 2 and follow this sequence until all of the bridge rectifiers outputs are connected. The positive outputs should connect to positive outputs. The negative outputs should connect to negative outputs.

22. Solder the bridge rectifiers' outputs to one end of the capacitor (positive to positive, negative to negative).

23. Solder one end of the LED to the positive end of the capacitor. Solder the other end of the LED to the negative 2.20 resistor. Solder the positive end of the resistor to the negative end of the switch and the positive end of the switch to the negative end of the capacitor.

Addendum B

Testing and Test Results

24. Place the energy harvesting pad on a flat surface. Then put the notebook on top of the pad. Because of the sensitivity of the piezoelectric sensors, be careful not to put anything near or on the notepad. The sensors are susceptible to generating energy through vibrations.

25. Attach an alligator clip to the negative voltmeter wire and then attach the alligator clip to the connection of the negative lead of the capacitor on the energy harvesting pad. Do the same for the positive alligator clip.

26. Turn on the voltmeter and dissipate any energy by turning on the switch at the bottom of the board and touch the volt meter sensor to the positive and negative leads simultaneously. Wait until the voltmeter reads “0”.

27. Obtain a rolling pin/dowel and start rolling the dowel/rolling pin back and forth 5 times. Start at the bottom of the notepad as one and go all the way up the notepad as two. Roll the dowel/rolling pin by using equal amount of speed and pressure from the wrists.

28. After the fifth roll, place the dowel to the side and measure the energy harvested by touching the positive voltmeter wire to the positive lead. Record the peak value in volts.

29. Repeat steps 26 to 28 for a total of 60 trials and then test 60 trials of 10 rolls, 20 rolls, and 30 rolls.

In testing the energy harvesting pad, a consecutive number of rolls (5, 10, 20, and 30 rolls) of a wooden dowel were made across the pad, each roll being made at the same speed and with the same amount of pressure being applied when rolling the dowel. After each trial, the LED light was turned on to dissipate the energy stored in the pad before the next test. The same materials were used during each experiment, and tests were run on the same flat surface.

In the tests, the independent variable was the number of rolls (5 rolls, 10 rolls, 20 rolls, 30 rolls) made. Each number of rolls was done 60 times. Energy was measured in Volts using a Volt meter. For the testing, the LED installed on the pad required a minimum application of 1.2 volts to turn the LED on. For every test, the light switch was turned on and tested to reveal that the stipulated number of volts generated with the piezoelectric pad had significantly increased. The data presented below confirms this fact. However, it was noted during the tests that the LED was not able to remain on for very long. The LED's light intensity increased based on the number of rolls made and the LED remained on for approximately 1 second, or less. This indicates that a next step in improving performance of the pad is to reduce energy dissipation by increasing capacitance.

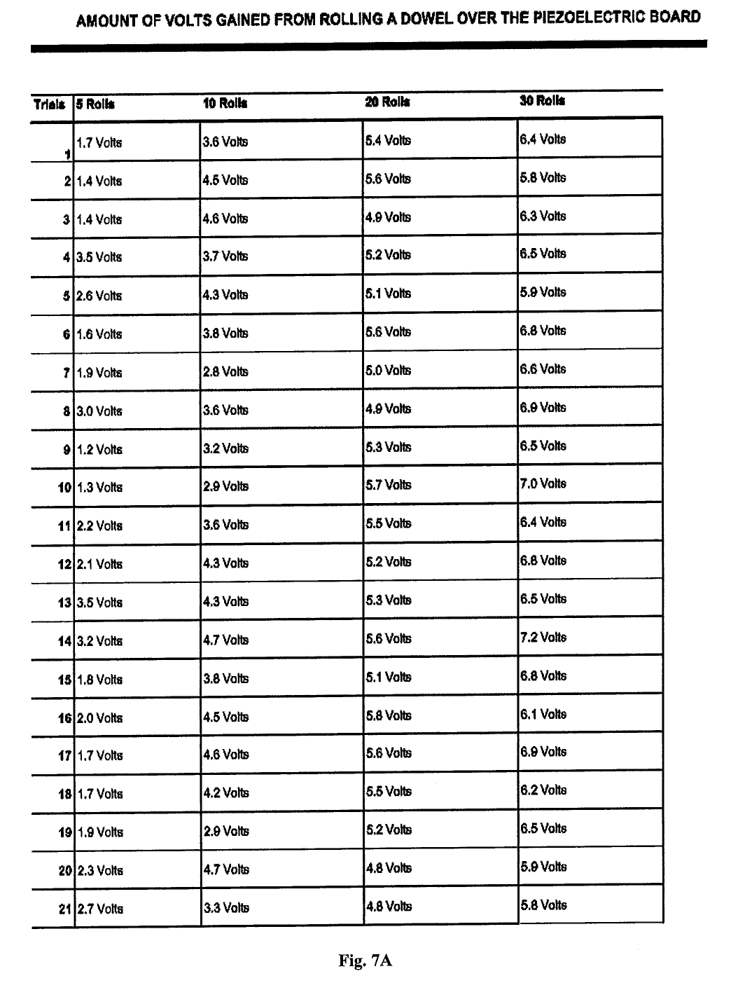

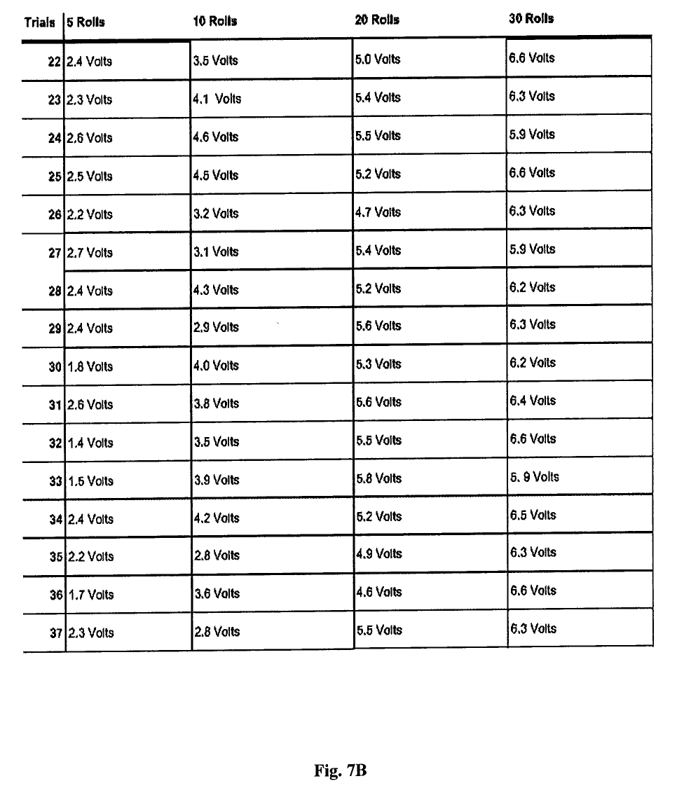

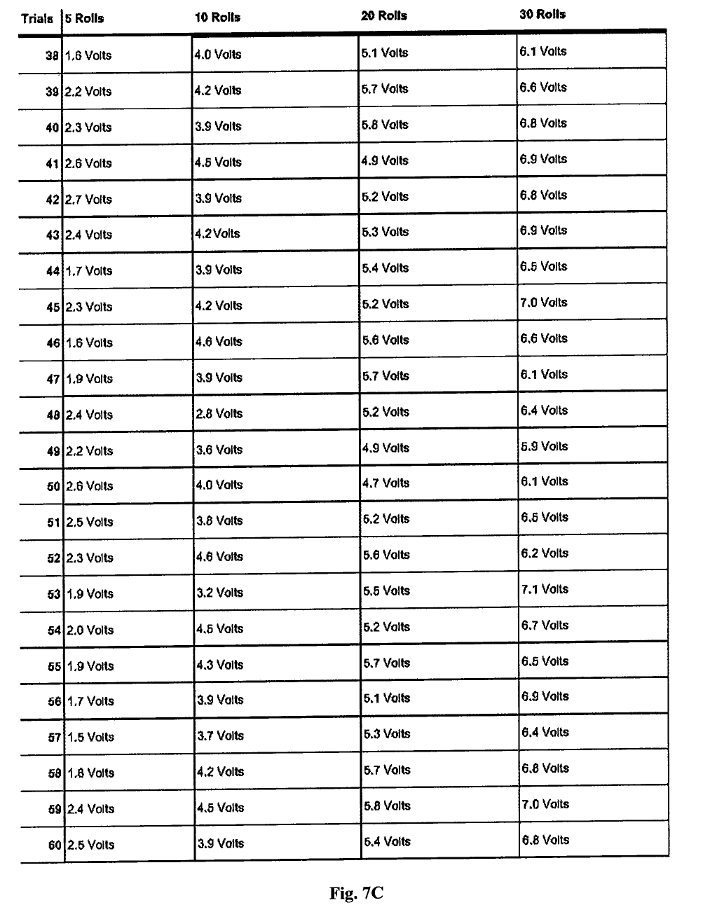

The charts, tables, and graphs shown in FIGS. 7-11 illustrate the results of the testing:

The chart of FIGS. 7A, 7B, and 7C show the amount of voltage obtained from each trial at 5, 10, 20, and 30 rolls.

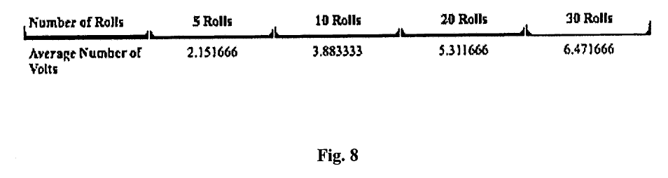

The chart of FIG. 8 shows the averages of the volts gained from 5, 10, 20, and 30 rolls.

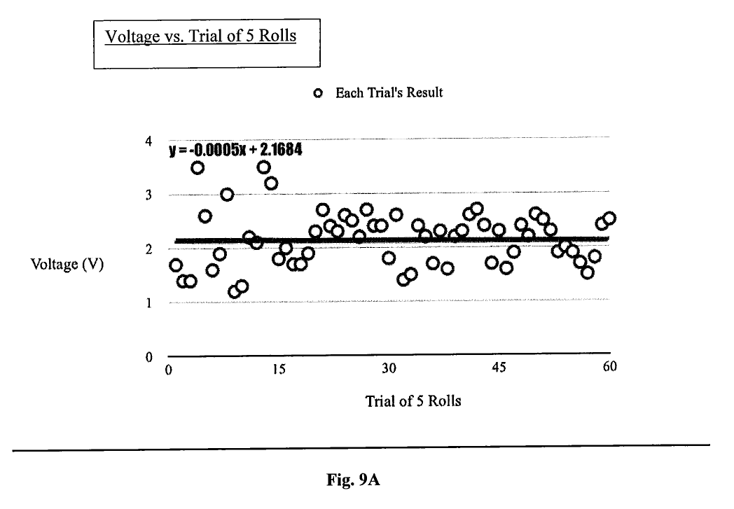

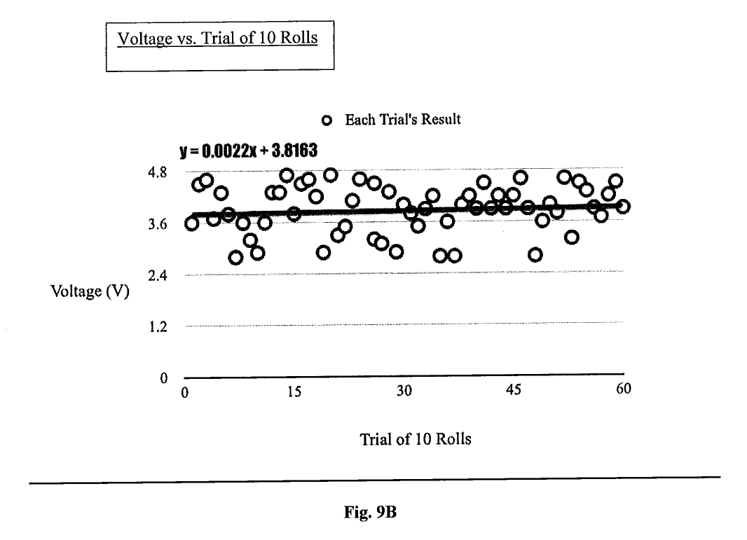

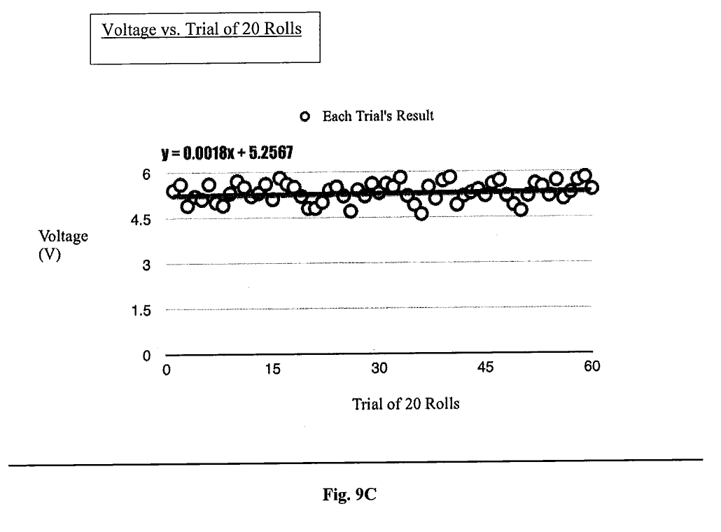

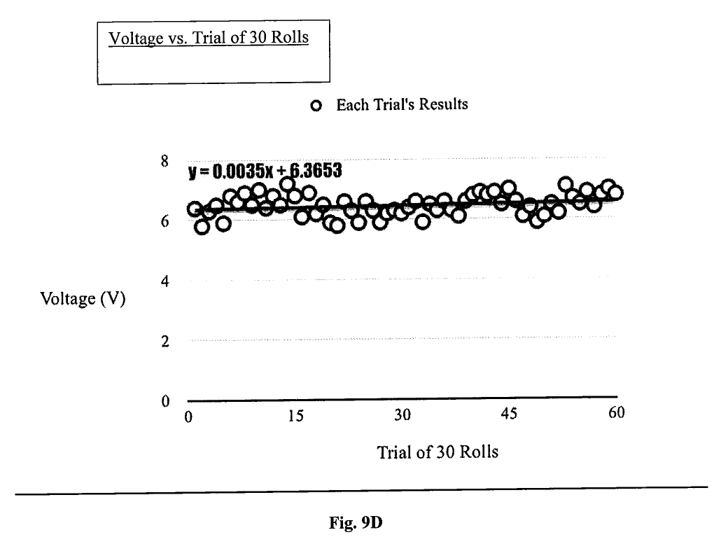

The scatter plot graphs of FIGS. 9A-9D show each trial's number of millivolts gained from rolling the dowel (5 rolls, 10 rolls, 20 rolls, 30 rolls). Each graph also includes a line of best fit with the line's equation put onto the graph.

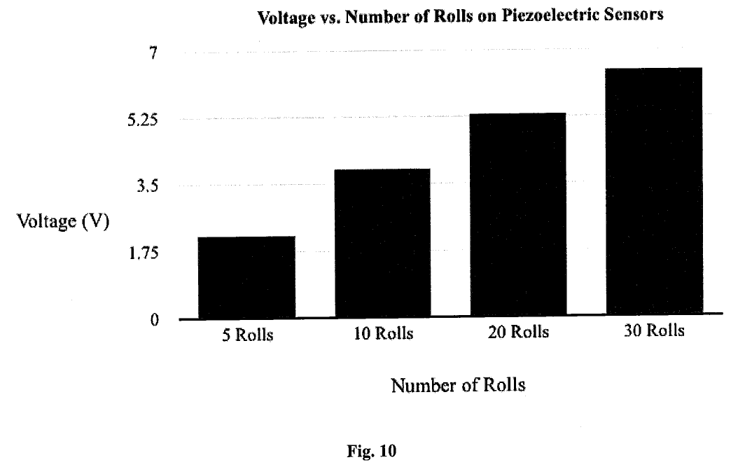

The bar graph of FIG. 10 shows the average amount of millivolts gained from each number of rolls. It will be noted that the average gradually increases as the number of rolls increases.

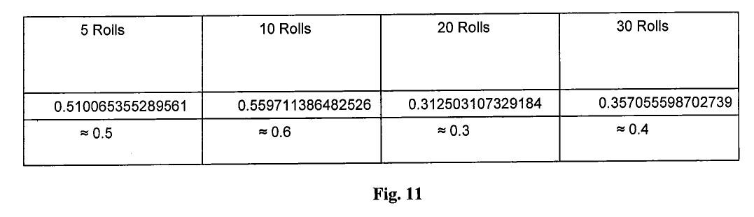

The table of FIG. 11 shows the standard deviation for all of the trials.

Addendum C

Analysis of Test Results

The results of the testing demonstrate that more voltage was gained from rolling the dowel 30 times than for all the other numbered rolls. The largest amount of voltage gained from 30 rolls was 7.2 volts. The smallest amount of voltage gained from the piezoelectric pad was 1.2 volts for 5 rolls. The results indicate that more rolls produce a greater generation of energy due to the pad's ability to store controlled kinetic energy.

The results indicate an increase over previous pad designs where the pad was only capable of storing millivolts of energy. Comparing the averages from the previous pad design with the pad design of the present invention, for five rolls the percentage increased by 9.14%, for ten rolls the increase was 8.02%, and for twenty rolls the increase was 8.38%. As the number of rolls increased, an increase in the amount of voltage generated was observed. This is because more mechanical stress is being put on the piezoelectric pad over a longer period of time; and, as such, the results support the hypothesis that placing the pad under stress for a longer period of time will result in more energy being generated.

By looking at the line of best fit on all four of the graphs in FIGS. 9A-9D respectively, it can be seen that all of the test results follow closely to the trend line, except for the five rolls test. The inventor expected this result because for five rolls, the total number of rolls is completed more quickly so that not enough pressure was put on the pad over a significant length of time. Overall, since the data in the graphs are generally close to the trend lines, this is an indication of the accuracy of the results as well as efficiency.

Various factors may have affected the results of the testing.

One area involved the testing method. The voltmeter used in the experiment had problems with wire connection. The wires needed support to remain in contact with the volt meter. Also, voltage readings fluctuated between 0.3 and 0.2 volts when the voltmeter was not properly connected. The connections could be improved by putting masking tape on top of the wires and tightly around the voltmeter to ensure the wires remain in contact.

Another cause of possible testing error was in not letting all the energy dissipate from the pad prior to the next test. This possible error was noted when higher peak voltages were observed. It was also observed during some trials that the measured voltages appeared to be less than what was seen. By properly controlling energy dissipation between each test, more reliable results could be obtained.

Finally, during some tests, in rolling over the hard surface of the pad, occasionally the dowel would slip off of the pad. In these instances, the test would have to be redone so the results obtained would be consistent. However, for future testing, use with a controlled machine to regulate the movement of the dowel over the pad would possibly improve the accuracy of the data.

In conclusion, the inventor's hypothesis that a pad such as constructed as described above would generate more energy which could be harvested if the pad was used frequently was proven. This was shown in the results; where, as the number of rolls increased, the amount of voltage generated increased with it. The smallest amount of voltage collected from all of the trials was 1.2 volts from doing five rolls. The largest amount of voltage collected from all of the trials was 7.2 volts from doing thirty rolls. These numbers have significantly increased from the previous pad design as the pad design has been significantly changed with regard to the use of different materials, diodes, and capacitance. Adding more bridge rectifiers into the design produced a better regulation of energy than in the previous design where having resistors regulate the flow of energy and cause the energy generated from a number of rolls to fluctuate much more widely than it does now in the design of the current invention. In the end, the new design is successful in being able to now properly turn on an LED light (which requires a minimum of needed a 1.2 volts to turn on) during every test. It was further demonstrated that with the new pad design that putting more mechanical stress put onto the piezoelectric pad meant more energy was generated by the pad.

As previously discussed, for the testing conducted, a piezoelectric pad was made using a wooden board with 42 piezoelectric sensors mounted on it. All of the sensor's wires were then connected as described above and a wooden dowel was then rolled over the piezoelectric pad 5, 10, 20, and 30 times with 60 repetitions for each number of rolls. Results from the tests were compared with those from tests for a previous design with the goal to improve upon the design of the pad so it can be used as a versatile storage device. This result was achieved with the amount of generated voltage surpassing that generated with the previous design for the same number of rolls and with the voltage not fluctuating as widely as with the previous design.

The result is a piezoelectric pad that can be implemented in a writing tablet, notebook, journal, or the like. The pad will be useful in a classroom setting, for example, because of the growing use of such devices in educational environments in the twenty first century. The pad would have the capability of charging other electronic devices after the device had been used for a certain period of time with the energy produced from it being regulated.

### EXHIBIT A

### References

“Alternating Current (AC) vs. Direct Current (DC).” Alternating Current (AC) vs. Direct Current (DC). Nap., n.d. Web. 27 Nov. 2016.
Barger, V., & Olsson, M. G. (1987). Classical electricity and magnetism: A contemporary perspective. Boston: Allyn and Bacon.
Benefits of Renewable Energy Use. (n.d.). Retrieved Aug. 3, 2015, from http://www.ucsusa.org/clean_energy/our-energy-choices/renewable-energy/public-benefits-of-renewable.html#.Vb1qRXA8KrU
Bordeau, S. P. (1982). Volts to Hertz—the rise of electricity: From the compass to the radio through the works of sixteen great men of science whose names are used in measuring electricity and magnetism. Minneapolis, Minn.: Burgess Pub.
Capacitors. (n.d.). Retrieved Aug. 3, 2015, from http://hyperphysics.phyastr.gsu.edu/hbase/electric/capac.html
Chegg.com. (n.d.). Retrieved Aug. 3, 2015, from http://www.chegg.com/homework-help/definitions/series-circuit-4
Electric circuit|electronics. (n.d.). Retrieved Aug. 3, 2015, from http://www.britannica.com/technology/electric-circuit
Galassi, C. (2000). Piezoelectric materials: Advances in science, technology, and applications. Dordrecht: Kluwer Academic.
Introduction to Diodes And Rectifiers. (n.d.). Retrieved Jan. 30, 2016, from http://www.allaboutcircuits.com/textbook/semiconductors/chpt-3/introduction-to-diodes-and-rectifiers/Kinetic energy|physics. (n.d.). Retrieved Jan. 10, 2016, from http://www.britannica.com/science/kinetic-energy
Lab 9: Piezoelectricity. (n.d.). Retrieved Aug. 3, 2015, from http://ocw.mitedu/courses/electrical-engineering-and-computer-science/6-5079-nanomaker-spring-2013/videos/lab-9-piezoelectricity/
“Ohm's Law.”(n.d.). Lecture. Retrieved from Website: http://ocw.mit.edu/courses/physics/8-022-physics-ii-electricity-and-magnetism-fall-2006/lecture-notes/lecture31.pdf
Parallel Circuits. (n.d.). Retrieved Jan. 3, 2015, from http://www.physicsclassroom.com/class/circuits/Lesson-4/Parallel-Circuits
Piezoelectric Energy Harvesting: Developments, Challenges, Future. (n.d.). Retrieved Aug. 3, 2015, from http://www.idtechex.com/research/articles/piezoelectric-energy-harvesting-developments-challenges-future-00005074.asp
Piezoelectric Materials Will Power Future Nanoscale Devices. (n.d.). Retrieved Aug. 5, 2015, from http://news.softpedia.com/news/Piezoelectric-Materials-Will-Power-Future-Nanoscale-Devices-117712.shtml
Resistors. (n.d.). Retrieved Aug. 3, 2015, from http://www.explainthatstuff.com/resistors.html
Resistors (Ohm's Law), Capacitors, and Inductors. (n.d.). Retrieved Aug. 3, 2015, from http://hades.mech.northwestern.edu/index.php/Resistors_(Ohm's_Law),_Capacitors,_and_Inductors
Requirements of a Circuit. (n.d.). Retrieved Aug. 3, 2015, from http://www.physicsclassroom.com/class/circuits/Lesson-2/Requirements-of-a-Circuit
Smart Materials. (n.d.). Retrieved Aug. 3, 2015, from http://depts.washington.edu/mictech/optics/sensors/week3.pdf
The Piezoelectric Effect—Piezoelectric Motors & Motion Systems. (n.d.). Retrieved Aug. 3, 2015, from http://www.nanomotion.com/piezo-ceramic-motor-technology/piezoelectric-effect/What
What is Piezo. (n.d.). Retrieved Aug. 3, 2015, from http://www.piezoinstitute.com/resources/what-is-piezo/
“What Is a Bridge Rectifier?” What Is a Bridge Rectifier, Half Wave Rectifiers, Semiconductor Diodes, Diode—Future Electronics. N.p., n.d. Web. 27 Nov. 2016.
What is Voltage?—Definition from WhatIs.com. (n.d.). Retrieved Aug. 23, 2015, from http://whatis.techtarget.com/definition/voltage
Yang, J. (2005). An introduction to the theory of piezoelectricity. New York: Springer.

Having thus described the invention, what is claimed and desired to be secured by Letters Patent is:

1. A renewable energy apparatus generating electricity using the piezoelectric effect, comprising:
a pad manufactured from a piezoelectric material;
a plurality of piezoelectric sensors mounted on the pad in a predetermined pattern for generating electrical energy due to kinetic energy resulting from motion of the pad or pressure applied to the pad;
at least one bridge rectifier circuit to which an electrical energy output from each sensor is supplied;
a capacitor to which an electrical energy output from the at least one bridge rectifier circuit is supplied, the capacitor storing electrical energy supplied to it;
an electrical outlet to which the capacitor is electrically connected and to which an electrical appliance to be charged is attached; and,
a switch interposed between the capacitor and the outlet by which, when the switch is activated, electrical energy stored in the capacitor is discharged from the capacitor in a controlled manner to recharge the electrical appliance.

2. The apparatus of claim 1 comprising a plurality of bridge rectifier circuits electrically connected in predetermined manner.

3. The apparatus of claim 2 in which the plurality of bridge rectifier circuits are electrically connected in parallel.

4. The apparatus of claim 2 further comprising a plurality of capacitors connected together to form a capacitor bank for storing the electrical energy.

5. The apparatus of claim 4 in which the electric energy outputs from respective groups of bridge rectifier circuits charge respective capacitors comprising the capacitor bank.

6. The apparatus of claim 1 further including an indicator to indicate when charging of the capacitor is occurring.

7. The apparatus of claim 6 in which the indicator is an LED which illuminates when capacitor charging is occurring.

8. The apparatus of claim 1 in the bridge rectifier circuit is comprised of diodes.
